(19) United States
(12) Patent Application Publication
(10) Pub. No.: US 2025/0264526 A1
(43) Pub. Date: Aug. 21, 2025

(54) INTERPOSER AND INSPECTION APPARATUS COMPRISING THE SAME

(71) Applicant: POINT ENGINEERING CO., LTD., Asan-si (KR)

(72) Inventors: Bum Mo AHN, Suwon-si (KR); Seung Ho PARK, Hwaseong-si (KR); Sung Hyun BYUN, Suwon-si (KR)

(73) Assignee: POINT ENGINEERING CO., LTD., Asan-si (KR)

(21) Appl. No.: 19/052,270

(22) Filed: Feb. 12, 2025

(30) Foreign Application Priority Data
Feb. 19, 2024 (KR) 10-2024-0023719

(51) Int. Cl. G01R 31/28

(52) U.S. Cl. CPC G01R 31/2889

(57) ABSTRACT

The present invention provides an interposer that is provided between an object to be inspected and electrically conductive pins, allowing the contact terminal of the object to be inspected and the tip of the electrically conductive pins to be indirectly electrically connected to each other, thereby preventing damage to the contact terminal, and an inspection apparatus comprising the same.

### CROSS-REFERENCE TO RELATED APPLICATIONS

The present application claims priority to Korean Patent Application No. 10-2024-0023719, filed Feb. 19, 2024, the entire contents of which is incorporated herein for all purposes by this reference.

### TECHNICAL FIELD

The present invention relates to an interposer and an inspection apparatus comprising the same.

### BACKGROUND

Inspection objects such as semiconductor devices or display panels undergo specific defect inspections to determine their defectiveness. For this purpose, the inspection object can be judged for defects by electrical signals from the inspection apparatus while being electrically connected to the inspection apparatus. Hereinafter, semiconductor devices will be exemplified among the inspection objects.

Semiconductor devices undergo reliability tests such as electrical characteristic inspections and function tests before shipment. A handler is mainly used to transport the manufactured semiconductor devices to the test apparatus and to classify the tested semiconductor devices. The handler transports multiple semiconductor devices to the test apparatus side and electrically connects the contact terminals of each semiconductor device to the electrically conductive pins of the test apparatus to proceed with the test process. At this time, the semiconductor device is electrically connected to the test apparatus through a test socket. Each tested semiconductor device is taken out from the test socket and classified according to the test results. Meanwhile, the test socket is mainly used for accommodating Ball Grid Array (BGA) devices, which use conductive balls as contact terminals among semiconductor devices.

In this testing process, when the contact terminals of the semiconductor device and the electrically conductive pins directly contact each other, there are cases where the tip of the electrically conductive pin presses the contact terminal, causing damage to the contact terminal.

### PRIOR ART DOCUMENTS

### Patent Documents

(Patent Document 1) Korean Patent Publication No. 10-2023-0130805
(Patent Document 2) Korean Patent Publication No. 10-2023-0112812

### SUMMARY

The present invention aims to provide an interposer, which is provided between an object to be inspected and electrically conductive pins, to indirectly electrically connect the contact terminal of the object to be inspected and the tip of the electrically conductive pins, thereby preventing damage to the contact terminal, and an inspection apparatus comprising the same.

In order to achieve the above-mentioned objectives, the interposer of the present invention comprises an anodized film obtained by anodizing a metal substrate and then removing the metal substrate; and a plurality of conductive needles formed in a through portion penetrating the anodized film.

Additionally, at least a portion of the conductive needles protrudes from a surface of the anodized film.

Furthermore, the through portion is a pore formed when forming the anodized film.

Moreover, the through portion is formed separately from the pore formed when forming the anodized film and has a larger opening area than the pore.

Additionally, the conductive needles comprise a first conductive part and a second conductive part, the first conductive part is formed of a metal having higher mechanical rigidity than the second conductive part, and the second conductive part is formed of a metal having higher electrical conductivity than the first conductive part, and at least a portion of the first conductive part protrudes from the surface of the anodized film.

Furthermore, the first conductive part comprises a first-1 conductive part with at least a portion protruding from an upper surface of the anodized film and a first-2 conductive part with at least a portion protruding from a lower surface of the anodized film, and the second conductive part is provided between the first-1 conductive part and the first-2 conductive part.

Additionally, the interposer comprises a formation region where the conductive needles are formed in clusters; and a non-formation region where the conductive needles are not provided.

Moreover, the interposer further comprises a protective layer formed on the surface of the anodized film so that the surface of the anodized film is not exposed.

Additionally, the interposer comprises a first region where the conductive needle protrudes from both sides of the anodized film; and a second region where the conductive needle protrudes from only one side of the anodized film.

Furthermore, the interposer further comprises a protective layer formed on the other side of the anodized film in the second region.

Meanwhile, the interposer of the present invention comprises a contact part having an anodized film obtained by anodizing a metal substrate and then removing the metal substrate, and a plurality of conductive needles formed in a through portion penetrating the anodized film and having at least a portion protruding from a surface of the anodized film; and a non-contact part formed surrounding the contact part at the periphery of the contact part and composed of a more flexible material than the anodized film.

Additionally, the non-contact part is formed of a polymer material.

Meanwhile, the inspection apparatus of the present invention comprises a first body on which an object to be inspected is placed; a second body having electrically conductive pins; and an interposer provided between the first body and the second body, wherein the interposer comprises an anodized film obtained by anodizing a metal substrate and then removing the metal substrate, and a plurality of conductive needles formed in a through portion penetrating the anodized film.

Additionally, at least a portion of the conductive needles protrudes from the surface of the anodized film.

The present invention provides an interposer that is provided between an object to be inspected and an electrically conductive pin, allowing the contact terminal of the object to be inspected and the tip of the electrically conductive pin to be electrically connected indirectly to each other, thereby preventing damage to the contact terminal, and an inspection apparatus comprising the same.

### BRIEF DESCRIPTION OF DRAWINGS

The above and other features of embodiments of the disclosure will become apparent by describing in detail embodiments thereof with reference to the accompanying drawings.

FIG. 1 is a view showing an interposer and an inspection apparatus comprising the same according to a preferred first embodiment of the present invention.

FIG. 2 is a perspective view of the interposer according to a preferred first embodiment of the present invention.

FIGS. 3 to 9 are views for explaining a method of manufacturing the interposer according to a preferred first embodiment of the present invention.

FIG. 10 is a view showing an interposer and an inspection apparatus comprising the same according to a preferred second embodiment of the present invention.

FIGS. 11 to 17 are views for explaining a method of manufacturing the interposer according to a preferred second embodiment of the present invention.

FIG. 18 is a view showing an interposer and an inspection apparatus comprising the same according to a preferred third embodiment of the present invention.

FIGS. 19 to 24 are views for explaining a method of manufacturing the interposer according to a preferred third embodiment of the present invention.

### DETAILED DESCRIPTION OF THE EMBODIMENTS

The following content merely illustrates the principles of the invention. Therefore, those skilled in the art can devise various devices that implement the principles of the invention and are included within the concept and scope of the invention, even if not explicitly described or shown in this specification. Additionally, all conditional terms and embodiments listed in this specification are intended, in principle, solely to aid in understanding the concept of the invention and should not be understood as limiting to the specifically listed embodiments and conditions.

The above-mentioned objectives, features, and advantages will become more apparent through the following detailed description in conjunction with the accompanying drawings, thereby enabling those skilled in the art to easily implement the technical idea of the invention.

The embodiments described in this specification will be explained with reference to ideal exemplary cross-sectional and/or perspective views of the invention. The thicknesses of the films and regions shown in these drawings are exaggerated for effective explanation of the technical content. The shapes in the exemplary drawings may be modified due to manufacturing techniques and/or tolerances. Therefore, the embodiments of the invention are not limited to the specific forms shown but also include variations in form generated by the manufacturing process. The technical terms used in this specification are merely used to describe specific embodiments and are not intended to limit the invention. Singular expressions include plural expressions unless the context clearly indicates otherwise. In this specification, terms such as “comprising” or “including” are intended to specify the presence of features, numbers, steps, operations, components, parts, or combinations thereof described in this specification, and do not preclude the possibility of the presence or addition of one or more other features, numbers, steps, operations, components, parts, or combinations thereof.

Hereinafter, preferred embodiments of the invention will be described in detail with reference to the accompanying drawings. In describing various embodiments below, components performing the same function will be given the same names and reference numbers for convenience, even if the embodiments are different. Additionally, the configurations and operations already described in other embodiments will be omitted for convenience.

### First Embodiment

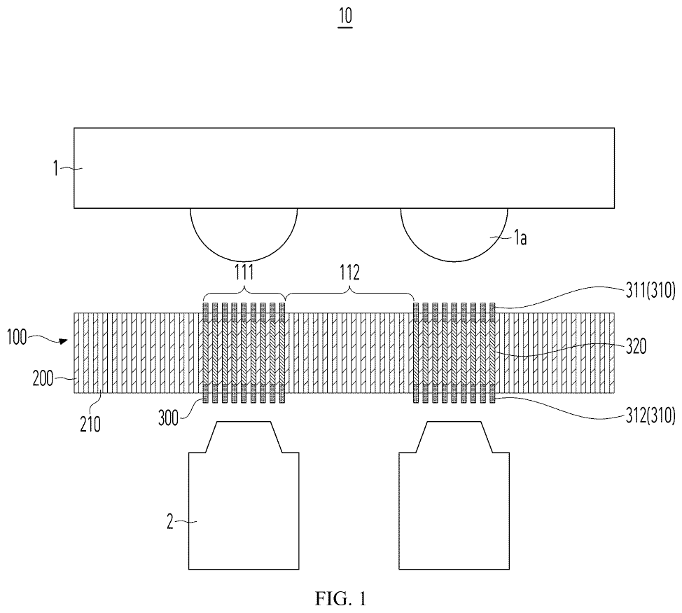

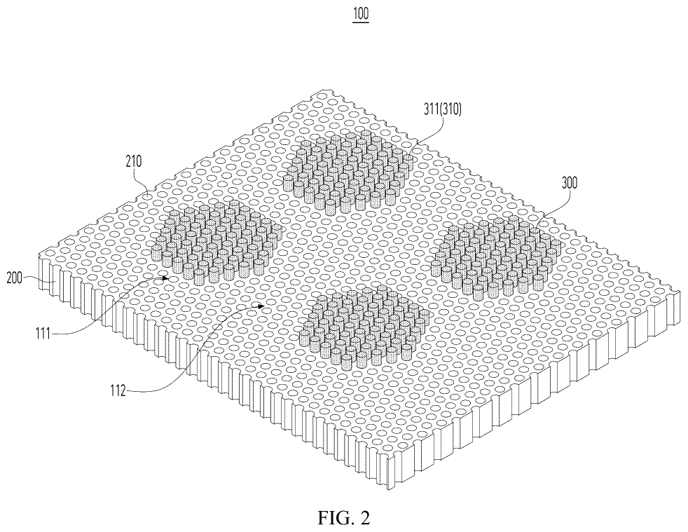

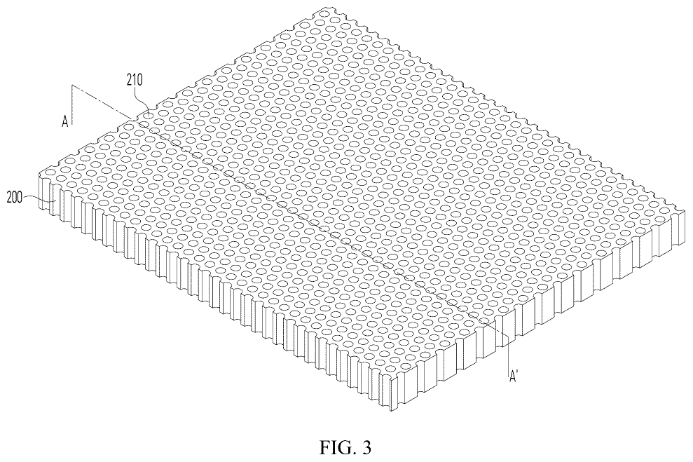

FIG. 1 is a view showing an interposer 100 and an inspection apparatus including the same according to a preferred first embodiment of the invention, FIG. 2 is a perspective view of the interposer 100 according to the preferred first embodiment of the invention, and FIGS. 3 to 9 are views for explaining the manufacturing method of the interposer 100 according to the preferred first embodiment of the invention.

The interposer 100 is an interposer for electrical connection and is provided between a first object and a second object to electrically connect the first object and the second object. The interposer 100 may be provided joined to at least one of the first object and the second object, or it may be provided in a form that is interposed between the first object and the second object without being joined to either of the two objects.

At least one of the first object and the second object may include a semiconductor device, memory chip, microprocessor chip, logic chip, light-emitting device, substrate, electrically conductive pin, or a combination thereof. For example, at least one of the first object and the second object may include a logic LSI (such as ASIC, FPGA, and ASSP), microprocessor (such as CPU and GPU), memory (such as DRAM, HMC (Hybrid Memory Cube), MRAM (Magnetic RAM), PCM (Phase-Change Memory), ReRAM (Resistive RAM), FeRAM (Ferroelectric RAM), and flash memory (NAND flash)), semiconductor light-emitting device (including LED, mini LED, micro LED, etc.), power device, analog IC (such as DC-AC converter and insulated gate bipolar transistor (IGBT)), MEMS (such as accelerometer, pressure sensor, vibrator, and gyro sensor), wireless device (such as GPS, FM, NFC, RFEM, MMIC, and WLAN), discrete device, BSI, CIS, camera module, CMOS, passive device, GAW filter, RF filter, RF IPD, APE, and BB.

For example, the interposer 100 may be provided between a semiconductor device and a substrate to electrically connect the semiconductor device and the substrate, or it may be provided between a semiconductor device and an electrically conductive pin to electrically connect the semiconductor device and the electrically conductive pin, or it may be provided between vertically adjacent semiconductor devices to electrically connect the vertically adjacent semiconductor devices, but it is not limited to these.

The interposer 100 described below may be a component used to inspect an object 1 to be inspected provided in an inspection apparatus 10. The inspection apparatus 10 may be an inspection apparatus used in a semiconductor manufacturing process or a display manufacturing process. The inspection apparatus 10 may be, for example, a probe card or an inspection apparatus including a test socket. Here, the first object is the object 1 to be inspected, and the second object is the electrically conductive pin 2. The inspection apparatus includes an electrically conductive pin 2 and a guide plate having a guide hole for accommodating the electrically conductive pin 2. The electrically conductive pin 2 may be a probe pin provided in a probe card or a socket pin provided in a test socket.

Referring to FIGS. 1 and 2, the inspection apparatus 10 includes a first body (not shown) on which the object 1 to be inspected is placed, a second body (not shown) having the electrically conductive pin 2, and an interposer 100 provided between the first body and the second body.

The interposer 100 is provided between the object 1 to be inspected and the electrically conductive pin 2.

The electrically conductive pin 2 electrically connects the terminal of the substrate and the object 1 to be inspected.

The interposer 100 includes an anodized film 200 obtained by anodizing a metal substrate and then removing the metal substrate, and a plurality of conductive needles 300 formed in a through portion 210 penetrating the anodized film 200.

The anodized film 200 is a film formed by anodizing a metal substrate. When the metal substrate is aluminum (Al) or an aluminum alloy, anodizing the metal substrate forms an anodized film 200 of aluminum oxide (Al₂O₃) material on the surface of the metal substrate. The metal substrate includes any metal material that can be anodized. The metal substrate may include, for example, tantalum (Ta), niobium (Nb), titanium (Ti), zirconium (Zr), hafnium (Hf), tungsten (W), antimony (Sb), or alloys thereof, but is not limited thereto.

The anodized film 200 formed as described above is divided into a barrier layer without pores formed vertically inside and a porous layer with pores formed inside. When the metal substrate with the anodized film 200 having a barrier layer and a porous layer formed on the surface is removed, only the anodized film 200 of aluminum oxide (Al₂O₃) material remains. The anodized film 200 may be formed in a structure where the barrier layer formed during anodizing is removed, and the pores penetrate vertically, or it may be formed in a structure where the barrier layer formed during anodizing remains, sealing one end of the pores vertically.

The anodized film 200 includes a through portion 210. The through portion 210 penetrates the anodized film 200.

The through portion 210 may be a pore formed when forming the anodized film 200. The through portion 210 is formed by opening the pores vertically by removing the barrier layer. The anodized film 200 includes a plurality of through portions 210, and the through portions 210 have a diameter of 10 nm or more and less than 100 nm. The pitch between adjacent through portions 210 is 20 nm or more and 200 nm or less.

Alternatively, the through portion 210 may be formed separately from the pores formed when forming the anodized film 200 and may have a larger opening area than the pores. In this case, the through portion 210 may be formed by etching a part of the anodized film 200 after forming the anodized film 200. The through portion 210 formed by separate etching has an opening width of 100 nm or more and less than 10 μm.

The conductive needle 300 is formed in the through portion 210. The conductive needle 300 is formed of a conductive material and preferably of a metal material.

The conductive needles 300 protrude at least partially from the surface of the anodized film 200. Multiple conductive needles 300 protrude from the surface of the anodized film 200 while being spaced apart from each other. One contact terminal 1a of the object to be inspected can contact multiple conductive needles 300. This prevents surface damage to the contact terminal 1a.

Comparing a non-protruding structure where the conductive needles 300 do not protrude from the surface of the anodized film 200 with a protruding structure where the conductive needles 300 do protrude from the surface of the anodized film 200, in the non-protruding structure, the surface of the anodized film 200 and multiple conductive needles 300 together contact the contact terminal 1a, whereas in the protruding structure, only multiple conductive needles 300 contact the contact terminal 1a.

A Ball Grid Array (BGA) using conductive balls as the contact terminals 1a of the object to be inspected 1 has each conductive ball formed with a hemispherical cross-section. When inspecting an object 1 with such contact terminals 1a, in the protruding structure, since at least some of the multiple conductive needles 300 penetrate into the contact terminal 1a and contact it, the number of conductive needles 300 contacting the contact terminal 1a is greater than in the non-protruding structure, thereby improving the reliability of the connection.

The conductive needles 300 comprise a first conductive part 310 and a second conductive part 320.

At least a portion of the first conductive part 310 protrudes from the surface of the anodized film 200. On the other hand, the second conductive part 320 is provided inside the through portion 210 and does not protrude from the surface of the anodized film 200.

The first conductive part 310 comprises a first-1 conductive part 311 with at least a portion protruding from the upper surface of the anodized film 200 and a first-2 conductive part 312 with at least a portion protruding from the lower surface of the anodized film 200. In this case, the second conductive part 320 is provided between the first-1 conductive part 311 and the first-2 conductive part 312.

Since the first conductive part 310 directly contacts surrounding components (the object to be inspected 1 or the electrically conductive pin 20), it needs to have higher mechanical rigidity than the second conductive part 320. On the other hand, since the second conductive part 320 does not directly contact surrounding components (the object to be inspected 1 or the electrically conductive pin 20), it does not need high mechanical rigidity but instead needs high electrical conductivity.

The first conductive part 310 is preferably formed of a metal with relatively higher mechanical rigidity than the second conductive part 320, such as rhodium (Rd), platinum (Pt), iridium (Ir), palladium (Pd), nickel (Ni), manganese (Mn), tungsten (W), phosphorus (Ph) or their alloys, or palladium-cobalt (PdCo) alloy, palladium-nickel (PdNi) alloy, nickel-phosphorus (NiPh) alloy, nickel-manganese (NiMn), nickel-cobalt (NiCo) or nickel-tungsten (NiW) alloy. Additionally, the second conductive part 320 is preferably formed of a metal with relatively higher electrical conductivity than the first conductive part 310, such as copper (Cu), silver (Ag), gold (Au) or their alloys. However, it is not limited to these. Alternatively, if the interposer 100 is structured to be bonded to at least one of the first object and the second object, the second conductive part 320 may include at least one material selected from Cu, Al, W, Au, Ag, Mo, Ta or their alloys, and the first conductive part 310 may include at least one material selected from Sn, AgSn, Au, PbSn, SnAgCu, SnAgBi, AuSn, In, InSn or Sn. For example, the second conductive part 320 may be made of copper (Cu) or an alloy mainly composed of copper (Cu), and the first conductive part 310 may be made of tin (Sn) or an alloy mainly composed of tin (Sn).

While the entire second conductive part 320 is provided inside the through portion 210, a portion of the first conductive part 310 protrudes from the surface of the anodized film 200, and the remaining part of the first conductive part 310 is provided inside the through portion 210. As a portion of the first conductive part 310, which is made of a metal with relatively higher mechanical rigidity than the second conductive part 320, is embedded inside the anodized film 200, the anodized film 200 can more firmly support the first conductive part 310 when it contacts surrounding components.

The interposer 100 comprises a formation region 111 where the conductive needles 300 are formed in clusters and a non-formation region 112 where the conductive needles 300 are not provided. The formation region 111 corresponds to one contact terminal 1a of the object to be inspected 1, and the non-formation region 112 does not correspond to the contact terminal 1a. Therefore, the formation region 111 is formed to be equal to or greater than the number of contact terminals 1a of the object to be inspected 1.

The non-formation region 112 is provided around the formation region 111, and when viewed in plan, the formation region 111 is surrounded by the non-formation region 112.

In the formation region 111, multiple conductive needles 300 protrude from the surface of the anodized film 200 and can electrically connect to one contact terminal 1a.

In the formation region 111, the conductive needles 333 not only protrude from the upper surface of the anodized film 200 to electrically connect to the contact terminal 1a but also protrude from the lower surface of the anodized film 200 to electrically connect to the electrically conductive pin 2. In this case, the part that physically contacts the contact terminal 1a may be the first-1 conductive part 311, and the part that physically contacts the electrically conductive pin 2 may be the first-2 conductive part 312.

The through portion 210 of the non-formation region 112 is provided in an empty form. As the through portion 210 of the anodized film 200 is provided in an empty form, it exhibits an insulating effect, preventing the electrically conductive pin 2 from deteriorating due to the high temperature of the object to be inspected 1 in high-temperature environment tests such as burn-in tests, and maintaining the positional accuracy between the contact terminal 1a and the electrically conductive pin 2.

Hereinafter, a method of manufacturing the interposer 100 according to the first embodiment will be described with reference to FIGS. 3 to 9.

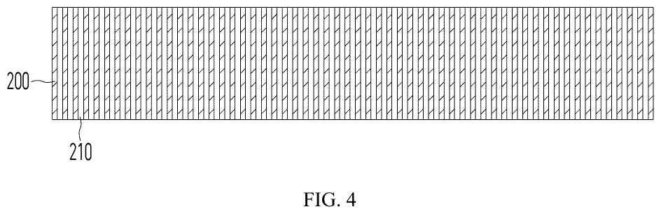

First, referring to FIGS. 3 and 4, a step of manufacturing the anodized film 200 with the through portion 210 is performed. FIG. 3 is a perspective view of the anodized film 200 with the through portion 210 formed, and FIG. 4 is a cross-sectional view taken along line A-A′ of FIG. 3.

The anodized film 200 is a film formed by anodizing a metal substrate. The anodized film 200 includes the through portion 210. The through portion 210 penetrates the anodized film 200.

The through portion 210 may be a pore formed when forming the anodized film 200. In this case, the through portion 210 is formed by opening the pore up and down by removing the barrier layer. The anodized film 200 includes multiple through portions 210, and the through portions 210 have a diameter of 10 nm or more and less than 100 nm. The pitch between adjacent through portions 210 is 20 nm or more and 200 nm or less.

Alternatively, the through portion 210 may be formed separately from the pore formed when forming the anodized film 200 and may have a larger opening area than the pore. In this case, the through portion 210 may be formed by etching a part of the anodized film 200 after forming the anodized film 200. The through portion 210 formed by separate etching has an opening width of 100 nm or more and less than 10 μm.

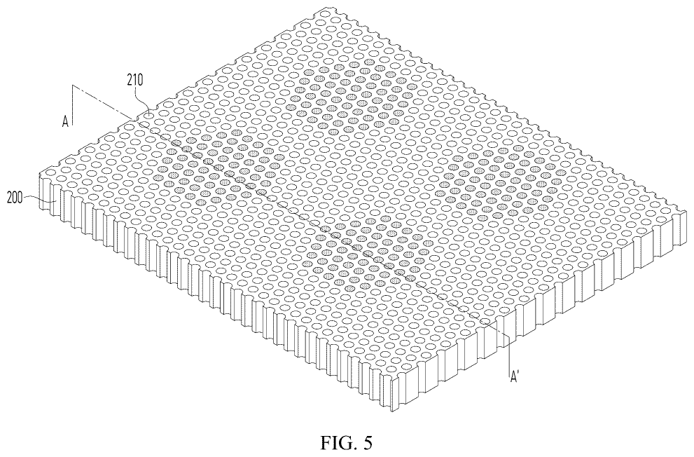

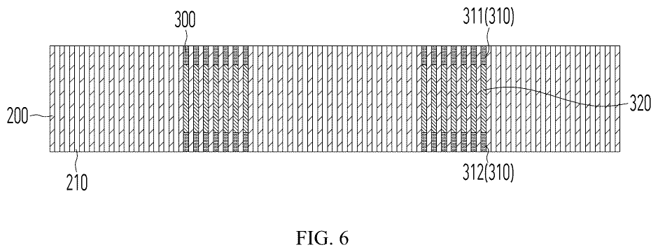

Next, referring to FIGS. 5 and 6, a step of forming the conductive needles 300 in the through portion 210 is performed. FIG. 5 is a perspective view of the structure in which the conductive needles 300 are formed in some of the through portions 210 of the anodized film 200, and FIG. 6 is a cross-sectional view taken along line A-A′ of FIG. 5.

Conductive needles 300 are formed in some of the multiple through portions 210. That is, in some of the multiple through portions 210, conductive needles 300 are provided, and in the remaining through portions 210, conductive needles 300 are not provided and remain empty.

Each conductive needle 300 can be formed by plating using a seed layer (not shown) in a state where the anodized film 200 is bonded to a carrier substrate with the seed layer (not shown). Each conductive needle 300 is provided in the order of the first-1 conductive part 311, the second conductive part 320, and the first-2 conductive part 312 from the top to the bottom. The second conductive part 320 is located between the first-1 conductive part 311 and the first-2 conductive part 312.

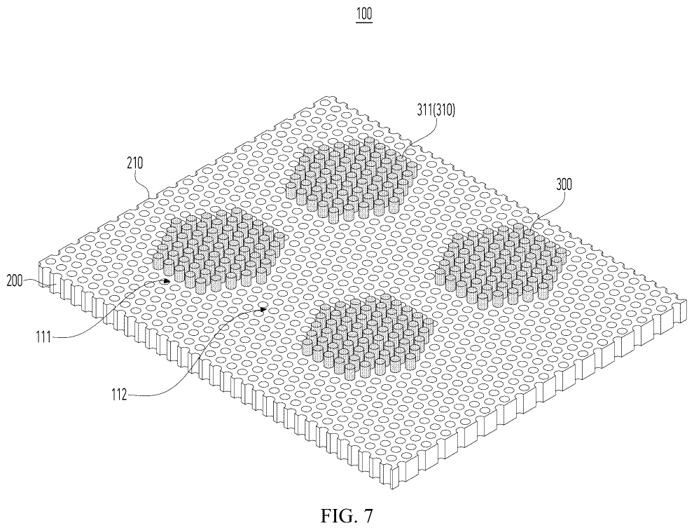

Next, referring to FIGS. 7 to 9, a step of making at least a portion of the conductive needles 300 protrude from the surface of the anodized film 200 is performed.

By etching the surface side of the anodized film 200 to make the anodized film 200 thinner, a portion of the conductive needles 300 protrudes from the surface of the anodized film 200. By removing the upper and lower surfaces of the anodized film 200 using a reactive solution that reacts only with the anodized film 200, both ends of the conductive needles 300, which were entirely embedded in the anodized film 200, protrude from the surface of the anodized film 200.

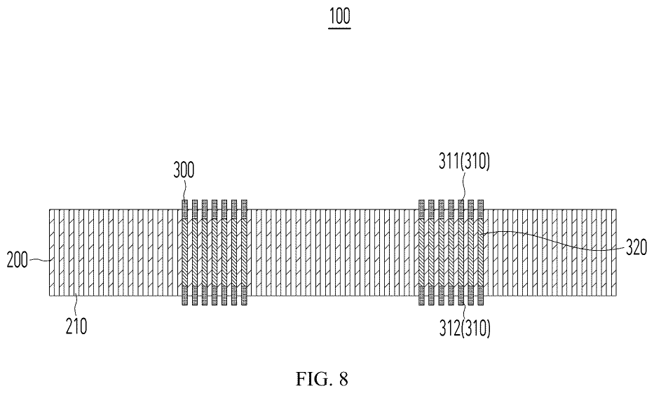

As shown in FIG. 8, a portion of the first-1 conductive part 311 is located inside the anodized film 200, allowing the anodized film 200 to support one end of the first-1 conductive part 311. Also, a portion of the first-2 conductive part 312 is located inside the anodized film 200, allowing the anodized film 200 to support one end of the first-2 conductive part 312. The second conductive part 320 remains embedded and does not protrude from the surface of the anodized film 200.

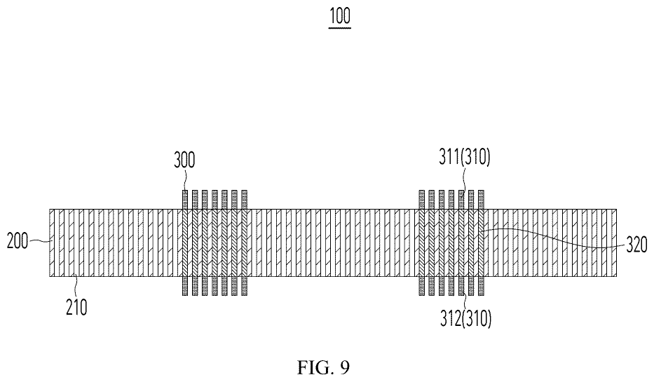

As shown in FIG. 9, the first-1 conductive part 311 and the first-2 conductive part 312 can protrude entirely from the surface of the anodized film 200. However, in this case, it is preferable that the second conductive part 320 is entirely embedded within the anodized film 200. This is because the second conductive part 320 has relatively higher electrical conductivity compared to the first conductive part 310 but is made of a metal material with high ductility. If the second conductive part 320 protrudes from the surface of the anodized film 200, the self-supporting property of the conductive needle 300 would be reduced.

### Second Embodiment

Next, a second embodiment according to the present invention will be described. The second embodiment described below will focus on the characteristic components compared to the first embodiment, and descriptions of components that are the same or similar to those in the first embodiment will be omitted as much as possible.

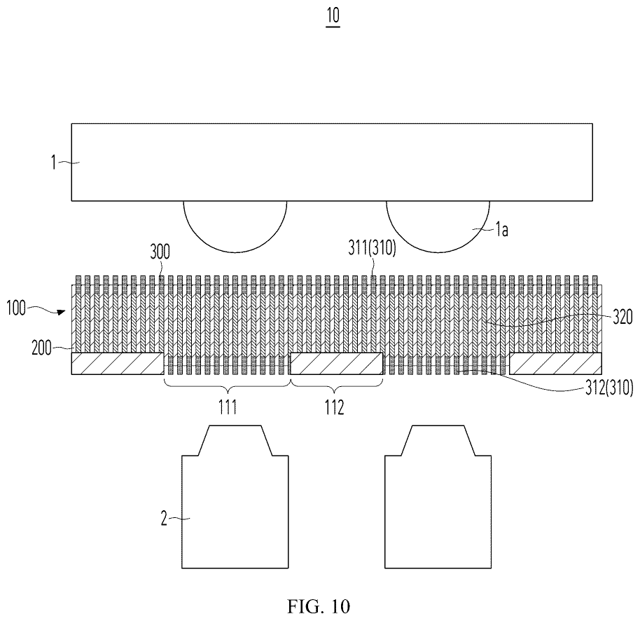

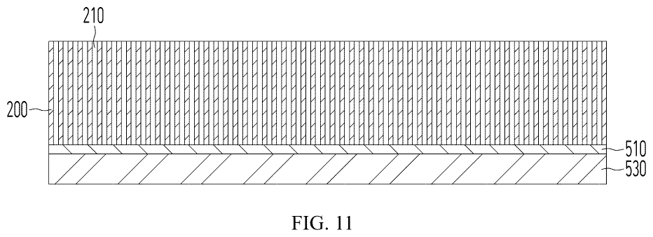

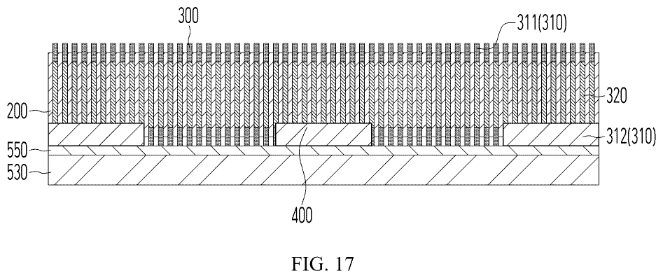

FIG. 10 is a view showing an interposer 100 according to a preferred second embodiment of the present invention and an inspection apparatus including the same, and FIGS. 11 to 17 are views for explaining a method of manufacturing the interposer 100 according to the preferred second embodiment of the present invention.

Referring to FIG. 10, the inspection apparatus 10 includes a first body (not shown) on which an object to be inspected 1 is placed, a second body (not shown) provided with electrically conductive pins 2, and an interposer 100 provided between the first body and the second body.

The interposer 100 is provided between the object to be inspected 1 and the electrically conductive pins 2.

The electrically conductive pins 2 electrically connect the terminals of the substrate and the object to be inspected 1.

The interposer 100 comprises an anodized film 200 obtained by anodizing a metal substrate and then removing the metal substrate, and a plurality of conductive needles 300 formed in a through portion 210 penetrating the anodized film 200.

The anodized film 200 is a film formed by anodizing a metal substrate. The anodized film 200 includes a through portion 210. The through portion 210 penetrates the anodized film 200.

The through portion 210 may be a pore formed when forming the anodized film 200. The through portion 210 is formed by removing the barrier layer, thereby opening the pore up and down. The anodized film 200 includes a plurality of through portions 210, and the through portions 210 have a diameter of 10 nm or more and less than 100 nm. The pitch between adjacent through portions 210 is 20 nm or more and 200 nm or less. Alternatively, the through portion 210 may be formed separately from the pore formed when forming the anodized film 200 and may have a larger opening area than the pore. In this case, the through portion 210 may be formed by etching a part of the anodized film 200 after forming the anodized film 200. The through portion 210 formed by separate etching has an opening width of 100 nm or more and less than 10 μm.

The conductive needle 300 is formed in the through portion 210. The conductive needle 300 is formed of a conductive material and preferably of a metal material.

The interposer 100 includes a first region 121 and a second region 122.

The first region 121 is an area where the object to be inspected 1 and the electrically conductive pins 2 correspond to each other, and the conductive needle 300 protrudes from both sides of the anodized film 200. The second region 122 is an area where the object to be inspected 1 and the electrically conductive pins 2 do not correspond to each other, and the conductive needle 300 protrudes from only one side of the anodized film 200. Accordingly, on one side of the anodized film 200, the conductive needle 300 protrudes entirely from the surface of the anodized film, while on the other side of the anodized film 200, both the configuration where the conductive needle 300 protrudes from the surface of the anodized film and the configuration where it does not protrude coexist.

The conductive needle 300 in the first region 121 includes a first conductive part 310 and a second conductive part 320. At least a portion of the first conductive part 310 protrudes from the surface of the anodized film 200. On the other hand, the second conductive part 320 is provided inside the through portion 210 and does not protrude from the surface of the anodized film 200. The first conductive part 310 includes a first-1 conductive part 311 with at least a portion protruding from the upper surface of the anodized film 200 and a first-2 conductive part 312 with at least a portion protruding from the lower surface of the anodized film 200. In this case, the second conductive part 320 is provided between the first-1 conductive part 311 and the first-2 conductive part 312.

Since the first conductive part 310 is a part that directly contacts the surrounding components (the object to be inspected 1 or the electrically conductive pins 20), it needs to have higher mechanical rigidity compared to the second conductive part 320. On the other hand, since the second conductive part 320 is not a part that directly contacts the surrounding components (the object to be inspected 1 or the electrically conductive pins 20), it does not need to have high mechanical rigidity but needs to have high electrical conductivity.

The first conductive part 310 is preferably formed of a metal with relatively higher mechanical rigidity compared to the second conductive part 320, such as rhodium (Rd), platinum (Pt), iridium (Ir), palladium (Pd), nickel (Ni), manganese (Mn), tungsten (W), phosphorus (Ph) or their alloys, or palladium-cobalt (PdCo) alloy, palladium-nickel (PdNi) alloy, nickel-phosphorus (NiPh) alloy, nickel-manganese (NiMn), nickel-cobalt (NiCo) or nickel-tungsten (NiW) alloy. Additionally, the second conductive part 320 is preferably formed of a metal with relatively higher electrical conductivity compared to the first conductive part 310, such as copper (Cu), silver (Ag), gold (Au) or their alloys. However, it is not limited to these. Alternatively, if the interposer 100 is structured to be bonded to at least one of the first object and the second object, the second conductive part 320 may include at least one material selected from Cu, Al, W, Au, Ag, Mo, Ta or alloys containing these, and the first conductive part 310 may include at least one material selected from Sn, AgSn, Au, PbSn, SnAgCu, SnAgBi, AuSn, In, InSn or alloys containing Sn. For example, the second conductive part 320 may be made of copper (Cu) or an alloy material mainly composed of copper (Cu), and the first conductive part 320 may be made of tin (Sn) or an alloy material mainly composed of tin (Sn).

While the entire second conductive part 320 is provided inside the through portion 210, a part of the first conductive part 310 protrudes from the surface of the anodized film 200, and the remaining part of the first conductive part 310 is provided inside the through portion 210. As a part of the first conductive part 310, which is made of a metal with relatively higher mechanical rigidity compared to the second conductive part 320, is embedded inside the anodized film 200, the anodized film 200 can more firmly support the first conductive part 310 when the first conductive part 310 contacts the surrounding components.

In the second region 122, the conductive needle 300 is provided protruding from one side of the anodized film 200, and a protective layer 400 is formed on the other side of the anodized film 200. The protective layer 400 is provided on the surface of the anodized film 200 so that the surface of the anodized film 200 is not exposed. The protective layer 400 may be made of an insulating material. Additionally, the protective layer 400 may be made of a material more flexible than the anodized film 200 to ensure the flexibility of the anodized film 200.

Hereinafter, a method of manufacturing the interposer 100 according to the second embodiment will be described with reference to FIGS. 11 to 17.

First, referring to FIG. 11, a step of manufacturing the anodized film 200 having the through portion 210 is performed.

The anodized film 200 is a film formed by anodizing a metal substrate. The anodized film 200 includes a through portion 210. The through portion 210 penetrates the anodized film 200.

The through portion 210 may be a pore formed when forming the anodized film 200. In this case, the through portion 210 is formed by removing the barrier layer, thereby opening the pore up and down. The anodized film 200 includes a plurality of through portions 210, and the through portions 210 have a diameter of 10 nm or more and less than 100 nm. The pitch between adjacent through portions 210 is 20 nm or more and 200 nm or less.

Alternatively, the through portion 210 may be formed separately from the pore formed when forming the anodized film 200 and may have a larger opening area than the pore. In this case, the through portion 210 may be formed by etching a part of the anodized film 200 after forming the anodized film 200. The through portion 210 formed by separate etching has an opening width of 100 nm or more and less than 10 μm.

After manufacturing the anodized film 200, a seed layer 510 and a carrier substrate 530 are provided on the lower part of the anodized film 200. The carrier substrate 530 is to facilitate handling of the anodized film 200 in subsequent processes, and the seed layer 510 is to be used in subsequent plating processes.

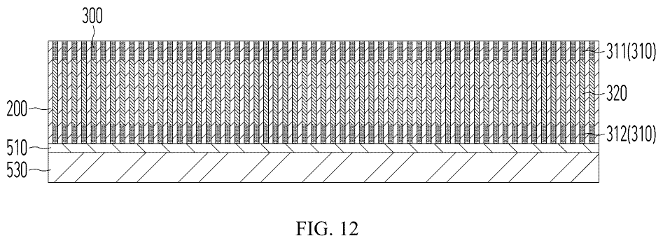

Next, referring to FIG. 12, a step of forming the conductive needle 300 in the through portion 210 is performed.

A plurality of conductive needles 300 are formed in the plurality of through portions 210. More specifically, conductive needles 300 are formed in all of the plurality of through portions 210.

Each conductive needle 300 can be formed by plating using the seed layer 510. Each conductive needle 300 is provided in the order of the first-1 conductive part 311, the second conductive part 320, and the first-2 conductive part 312 from the top to the bottom. The second conductive part 320 is located between the first-1 conductive part 311 and the first-2 conductive part 312.

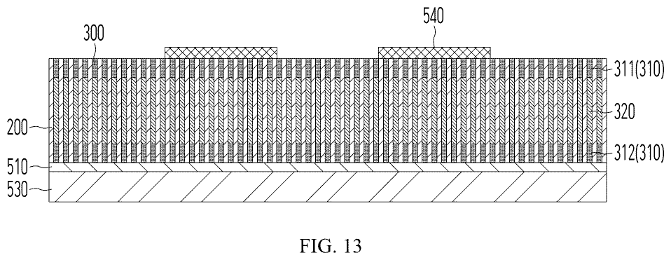

Next, referring to FIG. 13, a step of providing and patterning a patternable material 540 (e.g., photoresist) on the upper part of the anodized film 200 is performed. As a result, the patternable material 540 is provided on a part of the upper part of the anodized film 200.

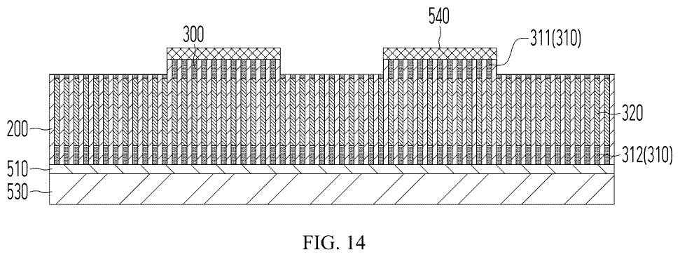

Next, referring to FIG. 14, a step of removing a part of the upper part of the anodized film 200 and a part of the upper part of the conductive needle 300 using the patternable material 540 as a mask is performed.

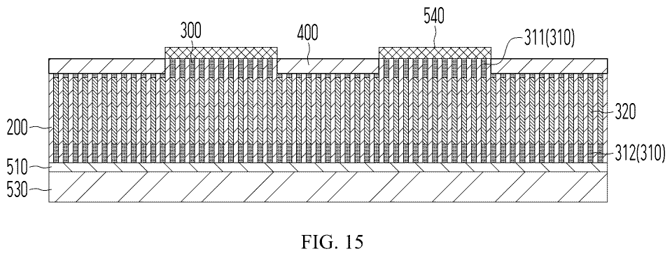

Next, referring to FIG. 15, a step of forming a protective layer 400 at the position removed in the previous step is performed.

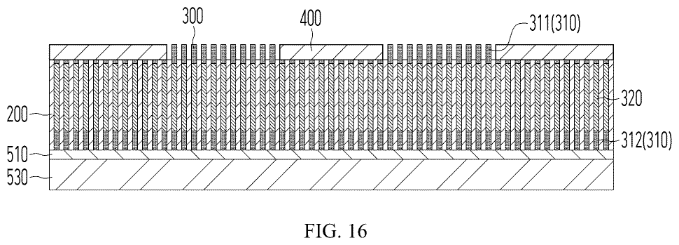

Next, referring to FIG. 16, the patternable material 540 is removed, and a portion of the anodized film 200 located under the patternable material 540 is etched.

Next, the previously fabricated structure is flipped upside down and bonded to a carrier substrate 530 provided with a bonding layer 550. Then, a portion of the upper part of the anodized film 200 is etched so that a part of the conductive needle 300 protrudes from the upper surface of the anodized film 200.

Subsequently, the bonding layer 550 and the carrier substrate 530 are removed to complete the fabrication of the interposer 100 according to the second embodiment.

### Third Embodiment

Next, a third embodiment according to the present invention will be described. However, the third embodiment described below will focus on the characteristic components compared to the first embodiment, and the description of components that are the same or similar to those of the first embodiment will be omitted as much as possible.

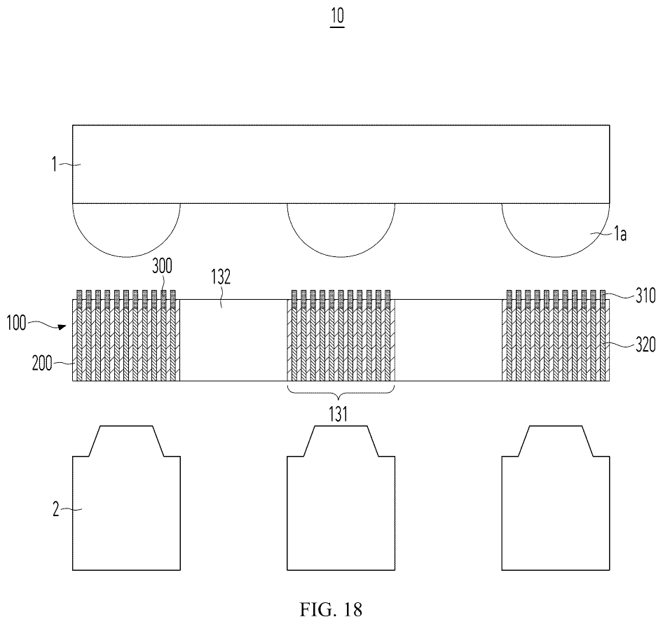

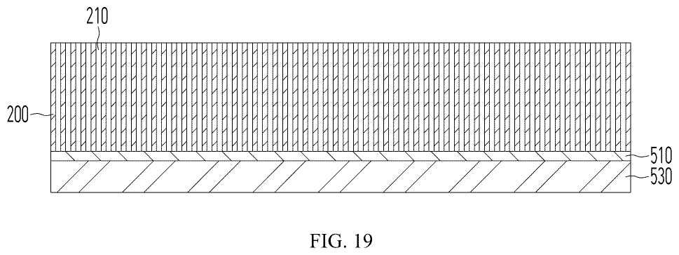

FIG. 18 is a view showing an interposer 100 according to a preferred third embodiment of the present invention and an inspection apparatus including the same, and FIGS. 19 to 24 are views for explaining a method of manufacturing the interposer 100 according to a preferred third embodiment of the present invention.

Referring to FIG. 18, the inspection apparatus 10 includes a first body (not shown) on which an object to be inspected 1 is placed, a second body (not shown) provided with electrically conductive pins 2, and an interposer 100 provided between the first body and the second body.

The interposer 100 is provided between the object to be inspected 1 and the electrically conductive pins 2.

The electrically conductive pins 2 electrically connect the terminals of the substrate and the object to be inspected 1.

The interposer 100 comprises a contact part 131 having an anodized film 200 obtained by anodizing a metal substrate and then removing the metal substrate, and a plurality of conductive needles 300 formed in a through portion 210 penetrating the anodized film 200 and having at least a portion protruding from a surface of the anodized film 200, and a non-contact part 132 formed surrounding the contact part 131 at the periphery of the contact part 131 and composed of a more flexible material than the anodized film 200.

The contact part 131 is a portion where the object to be inspected 1 and the electrically conductive pins 2 are electrically connected, and the non-contact part 132 is a portion where the object to be inspected 1 and the electrically conductive pins 2 are not electrically connected.

The contact part 131 comprises an anodized film 200 obtained by anodizing a metal substrate and then removing the metal substrate, and a plurality of conductive needles 300 formed in a through portion 210 penetrating the anodized film 200.

The anodized film 200 is a film formed by anodizing a metal substrate. The anodized film 200 includes a through portion 210. The through portion 210 penetrates the anodized film 200.

The through portion 210 may be a pore formed when forming the anodized film 200. The through portion 210 is formed by opening the pore up and down by removing the barrier layer. The anodized film 200 includes a plurality of through portions 210, and the through portions 210 have a diameter of 10 nm or more and less than 100 nm. The pitch between adjacent through portions 210 is 20 nm or more and 200 nm or less. Alternatively, the through portion 210 may be formed separately from the pore formed when forming the anodized film 200 and may have a larger opening area than the pore. In this case, the through portion 210 may be formed by etching a part of the anodized film 200 after forming the anodized film 200. The through portion 210 formed by separate etching has an opening width of 100 nm or more and less than 10 μm.

The conductive needle 300 is formed in the through portion 210. The conductive needle 300 is formed of a conductive material and preferably may be formed of a metal material.

The conductive needle 300 includes a first conductive part 310 and a second conductive part 320. The first conductive part 310 protrudes from the surface of the anodized film 200. On the other hand, the second conductive part 320 is provided inside the through portion 210 and does not protrude from the surface of the anodized film 200.

The first conductive part 310 is a metal having relatively higher mechanical rigidity than the second conductive part 320, and preferably may be formed of a metal selected from rhodium (Rd), platinum (Pt), iridium (Ir), palladium (Pd), nickel (Ni), manganese (Mn), tungsten (W), phosphorus (Ph) or alloys thereof, or palladium-cobalt (PdCo) alloy, palladium-nickel (PdNi) alloy, nickel-phosphorus (NiPh) alloy, nickel-manganese (NiMn), nickel-cobalt (NiCo) or nickel-tungsten (NiW) alloy. Also, the second conductive part 320 is a metal having relatively higher electrical conductivity than the first conductive part 310, and preferably may be formed of a metal selected from copper (Cu), silver (Ag), gold (Au) or alloys thereof. However, it is not limited thereto. Alternatively, when the interposer 100 is structured to be bonded to at least one of the first object and the second object, the second conductive part 320 may include a material selected from Cu, Al, W, Au, Ag, Mo, Ta or alloys thereof, and the first conductive part 310 may include a material selected from Sn, AgSn, Au, PbSn, SnAgCu, SnAgBi, AuSn, In, InSn or alloys thereof. For example, the second conductive part 320 may be a copper (Cu) or a copper (Cu)-based alloy material, and the first conductive part 320 may be a tin (Sn) or a tin (Sn)-based alloy material.

Hereinafter, a method of manufacturing the interposer 100 according to the third embodiment will be described with reference to FIGS. 19 to 24.

First, referring to FIG. 19, a step of manufacturing an anodized film 200 having a through portion 210 is performed.

The anodized film 200 is a film formed by anodizing a metal substrate. The anodized film 200 includes a through portion 210. The through portion 210 penetrates the anodized film 200.

The through portion 210 may be a pore formed when forming the anodized film 200. In this case, the through portion 210 is formed by opening the pore up and down by removing the barrier layer. The anodized film 200 includes a plurality of through portions 210, and the through portions 210 have a diameter of 10 nm or more and less than 100 nm. The pitch between adjacent through portions 210 is 20 nm or more and 200 nm or less.

Alternatively, the through portion 210 may be formed separately from the pore formed when forming the anodized film 200 and may have a larger opening area than the pore. In this case, the through portion 210 may be formed by etching a part of the anodized film 200 after forming the anodized film 200. The through portion 210 formed by separate etching has an opening width of 100 nm or more and less than 10 μm.

After manufacturing the anodized film 200, a seed layer 510 and a carrier substrate 530 are provided under the anodized film 200. The carrier substrate 530 is to facilitate the handling of the anodized film 200 in subsequent processes, and the seed layer 510 is to be used in subsequent plating processes.

Next, referring to FIG. 12, a step of forming a conductive needle 300 in the through portion 210 is performed.

A plurality of conductive needles 300 are formed in the plurality of through portions 210. More specifically, conductive needles 300 are formed in all of the plurality of through portions 210.

Each conductive needle 300 may be formed by plating using the seed layer 510. Each conductive needle 300 is provided in the order of a first-1 conductive part 311, a second conductive part 320, and a first-2 conductive part 312 from the top to the bottom. The second conductive part 320 is located between the first-1 conductive part 311 and the first-2 conductive part 312.

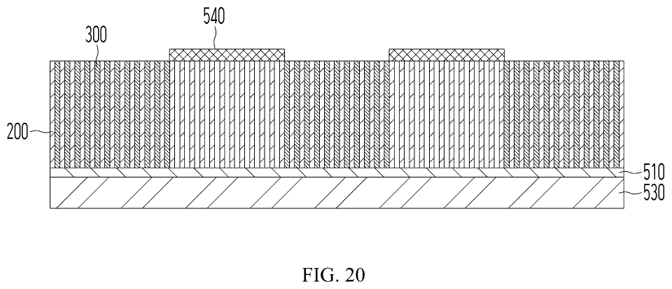

Next, referring to FIG. 20, a step of providing and patterning a patternable material 540 (e.g., photoresist) on the upper part of the anodized film 200 is performed. As a result, the patternable material 540 is provided on a part of the upper part of the anodized film 200. Subsequently, a plating process is performed to form conductive needles 300 in the through portions 210 where the patternable material 540 is not present.

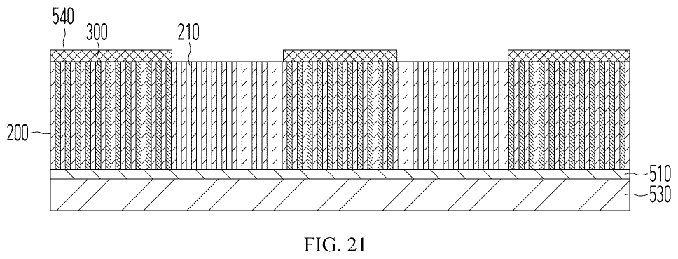

Next, referring to FIG. 21, the patternable material 540 is formed at the positions where the conductive needles 300 are formed, and the anodized film 200 at the positions where the conductive needles 300 are not formed is exposed.

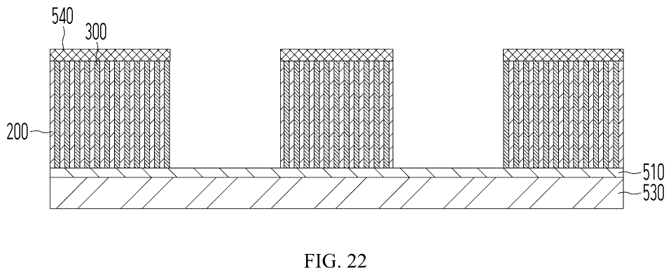

Next, referring to FIG. 22, the anodized film 200 is etched using the patternable material 540 as a mask.

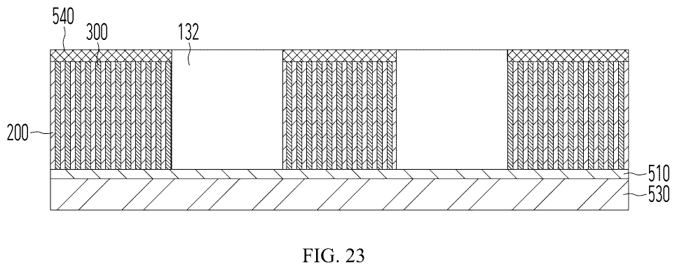

Next, referring to FIG. 23, a material more flexible than the anodized film 200 is provided at the positions where the anodized film 200 was etched and removed in the previous step to form the non-contact part 132. The material of the non-contact part 132 may be a polymer material.

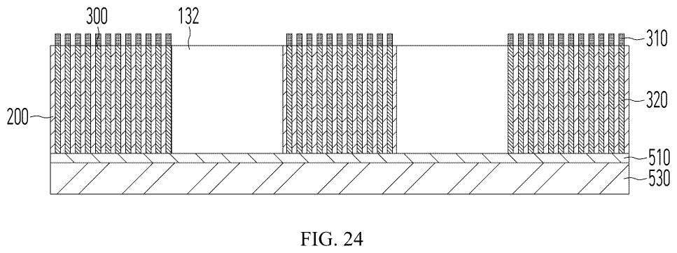

Next, referring to FIG. 24, after performing a planarization process on the upper surface, a plating process is performed so that a part of the conductive needle 300 protrudes from the upper surface of the anodized film 200. The part embedded inside the anodized film 200 is the second conductive part 320, and the first conductive part 310 is formed at the exposed end of the second conductive part 320 by the plating process. As a result, the first conductive part 310 protrudes from the upper surface of the anodized film 200.

Subsequently, the bonding layer 550 and the carrier substrate 530 are removed to complete the fabrication of the interposer 100 according to the third embodiment.

In the above, the interposer 100 has been described as a component provided between the object to be inspected 1 and the electrically conductive pins 2. However, the interposer 100 according to the preferred embodiments of the present invention is not limited thereto and may be provided between a semiconductor device and a substrate to electrically connect the semiconductor device and the substrate, or may be provided between vertically adjacent semiconductor devices to electrically connect the vertically adjacent semiconductor devices.

Furthermore, in the above description, the interposer (100) was illustrated and explained as a component that is interposed between the first object and the second object without being bonded to either of the two objects. However, the interposer (100) according to the preferred embodiments of the present invention is not limited to this and can be used for bonding the first object and the second object.

As described above, the preferred embodiments of the present invention have been explained with reference to the preferred embodiments, but those skilled in the art can make various modifications or changes to the present invention without departing from the spirit and scope of the present invention as set forth in the following claims.

What is claimed is:

1. An interposer comprising:
an anodized film obtained by anodizing a metal substrate and then removing the metal substrate; and
a conductive needle formed in a through portion penetrating the anodized film.

2. The interposer of claim 1, wherein
at least a portion of the conductive needle protrudes from a surface of the anodized film.

3. The interposer of claim 1, wherein
the through portion is a pore formed when forming the anodized film.

4. The interposer of claim 1, wherein
the through portion is formed separately from the pore formed when forming the anodized film and has a larger opening area than the pore.

5. The interposer of claim 1, wherein
the conductive needle comprises a first conductive part and a second conductive part,
the first conductive part is formed of a metal having higher mechanical rigidity than the second conductive part, and the second conductive part is formed of a metal having higher electrical conductivity than the first conductive part, and
at least a portion of the first conductive part protrudes from the surface of the anodized film.

6. The interposer of claim 5, wherein
the first conductive part comprises a first-1 conductive part with at least a portion protruding from an upper surface of the anodized film and a first-2 conductive part with at least a portion protruding from a lower surface of the anodized film, and
the second conductive part is provided between the first-1 conductive part and the first-2 conductive part.

7. The interposer of claim 1, comprising:
a formation region where the conductive needles are formed in clusters; and
a non-formation region where the conductive needles are not provided.

8. The interposer of claim 1, further comprising:
a protective layer formed on the surface of the anodized film so that the surface of the anodized film is not exposed.

9. The interposer of claim 1, comprising:
a first region where the conductive needle protrudes from both sides of the anodized film; and
a second region where the conductive needle protrudes from only one side of the anodized film.

10. The interposer of claim 9, further comprising:
a protective layer formed on the other side of the anodized film in the second region.

11. An interposer comprising:
a contact part having an anodized film obtained by anodizing a metal substrate and then removing the metal substrate, and a plurality of conductive needles formed in a through portion penetrating the anodized film and having at least a portion protruding from a surface of the anodized film; and
a non-contact part formed surrounding the contact part at the periphery of the contact part and composed of a more flexible material than the anodized film.

12. The interposer of claim 11, wherein
the non-contact part is formed of a polymer material.

13. An inspection apparatus comprising:
a first body on which an object to be inspected is placed;
a second body having electrically conductive pins; and
an interposer provided between the first body and the second body, wherein the interposer comprises
an anodized film obtained by anodizing a metal substrate and then removing the metal substrate, and
a plurality of conductive needles formed in a through portion penetrating the anodized film.

14. The inspection apparatus of claim 13, wherein
at least a portion of the conductive needle protrudes from the surface of the anodized film.
